(19) United States
(12) Patent Application Publication
(10) Pub. No.: US 2010/0320525 A1
(43) Pub. Date: Dec. 23, 2010

(54) NONVOLATILE SEMICONDUCTOR MEMORY DEVICE AND METHOD OF MANUFACTURING NONVOLATILE SEMICONDUCTOR MEMORY DEVICE

(76) Inventors: Satoshi NAGASHIMA, Kanagawa (JP); Nobuhito KAWADA, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/611,640

(22) Filed: Nov. 3, 2009

(30) Foreign Application Priority Data
Jun. 18, 2009 (JP) 2009-145764

(51) Int. Cl. H01L 29/792; H01L 21/336

(52) U.S. Cl. 257/324; 438/261; 257/E29.309; 257/E21.409

(57) ABSTRACT

A nonvolatile semiconductor memory device includes: fin-shaped control gate electrodes formed on an insulating layer; and a body layer having a channel region arranged to cross the control gate electrodes and embedded in the control gate electrodes sequentially via a first insulating layer, a charge storage layer, and a second insulating layer.

### CROSS-REFERENCE TO RELATED APPLICATIONS

This application is based upon and claims the benefit of priority from the prior Japanese Patent Application No. 2009-145764, filed on Jun. 18, 2009; the entire contents of which are incorporated herein by reference.

### BACKGROUND OF THE INVENTION

1. Field of the Invention

The present invention relates to a nonvolatile semiconductor memory device and a method of manufacturing the nonvolatile semiconductor memory device, and, more particularly is suitably applied to a nonvolatile semiconductor memory device in which a channel region is arranged on a gate electrode via a charge storage layer.

2. Description of the Related Art

To increase an integration degree of a nonvolatile semiconductor memory device, in general, memory cells are microminiaturized. When the memory cells are microminiaturized, in particular, in a NAND flash memory, controllability (a switching characteristic) of a drain current by a gate electric field falls and the number of electrons (the number of electrons per bit) that can be stored in a charge storage layer decreases. Therefore, there is a limit in the microminiaturization of the memory cell.

As a method of increasing the integration degree of the nonvolatile semiconductor memory device without microminiaturizing the memory cells, there is a method of laminating memory cells in the vertical direction.

For example, Japanese Patent Application Laid-Open No. 2009-60087 discloses a method of providing a bottom gate electrode on a substrate, providing a charge storage layer on the bottom gate electrode, and providing a semiconductor channel layer on the charge storage layer in a nonvolatile memory element.

However, in the method of laminating memory cells in the vertical direction, single crystal silicon cannot be used for a channel layer and polysilicon needs to be used. Therefore, because mobility of electrons in the channel layer falls and an ON current decreases, operation speed falls.

To improve the switching characteristic, a field effect transistor is formed in a fin structure. However, in terms of a process, it is difficult to laminate the fin structure in many layers in the NAND flash memory (when the fin structure is applied, because a control gate electrode and a charge storage layer need to be processed to meander up and down along a sectional shape of a fin, it is difficult to process the control gate electrode and the charge storage layer).

### BRIEF SUMMARY OF THE INVENTION

A nonvolatile semiconductor memory device according to an embodiment of the present invention comprises: fin-shaped control gate electrodes formed on an insulating layer; and a body layer having a channel region arranged to cross the control gate electrodes and embedded in the control gate electrodes sequentially via a first insulating layer, a charge storage layer, and a second insulating layer.

A nonvolatile semiconductor memory device according to an embodiment of the present invention comprises: control gate electrodes formed on an insulating layer; and a body layer formed of continuous grain silicon grain-grown in a direction crossing the control gate electrodes and arranged on the control gate electrodes to cross the control gate electrodes sequentially via a first insulating layer, a charge storage layer, and a second insulating layer.

A method of manufacturing a nonvolatile semiconductor memory device according to an embodiment of the present invention comprises: forming fin-shaped control gate electrodes on an insulating layer; forming grooves in the control gate electrodes; sequentially forming a first insulating layer, a charge storage layer, and a second insulating layer in the grooves; forming, on the insulating layer, a polysilicon layer embedded in the grooves; changing the polysilicon layer to a continuous grain silicon layer by crystal-growing the polysilicon layer in a direction of the grooves; and removing, by thinning the continuous grain silicon layer, the continuous grain silicon layer extruded onto the grooves and forming a body layer having a channel region embedded in the control gate electrodes sequentially via the first insulating layer, the charge storage layer, and the second insulating layer.

A method of manufacturing a nonvolatile semiconductor memory device according to an embodiment of the present invention comprises: forming fin-shaped control gate electrodes on an insulating layer; forming a sacrificial layer between the control gate electrodes; forming grooves in the control gate electrodes and the sacrificial layer; sequentially forming a first insulating layer, a charge storage layer, and a second insulating layer in the grooves; forming, on the insulating layer, a polysilicon layer embedded in the grooves; removing, by thinning the polysilicon layer, the polysilicon layer extruded onto the grooves and forming a body layer having a channel region embedded in the control gate electrodes sequentially via the first insulating layer, the charge storage layer, and the second insulating layer; forming a hollow section formed under the polysilicon layer between the control gate electrodes by removing the sacrificial layer between the control gate electrodes; and changing the polysilicon layer to a continuous grain silicon layer by performing thermal treatment of the polysilicon layer after forming the hollow section.

A method of manufacturing a nonvolatile semiconductor memory device according to an embodiment of the present invention comprises: forming control gate electrodes on an insulating layer; sequentially forming a first insulating layer, a charge storage layer, a second insulating layer, and a polysilicon layer on the control gate electrodes; changing the polysilicon layer to a continuous grain silicon layer by crystal-growing the polysilicon layer in a direction crossing the control gate electrodes; and forming, by processing the polysilicon layer to cross the control gate electrodes, a body layer arranged on the control gate electrodes to cross the control gate electrodes sequentially via the first insulating layer, the charge storage layer, and the second insulating layer.

### BRIEF DESCRIPTION OF THE DRAWINGS

FIG. 1 is a perspective view of a schematic configuration of a nonvolatile semiconductor memory device according to a first embodiment of the present invention;

FIGS. 2A and 2B are sectional views for explaining a method of manufacturing a nonvolatile semiconductor memory device according to a second embodiment of the present invention;

FIGS. 3A and 3B are sectional views for explaining the method of manufacturing a nonvolatile semiconductor memory device according to the second embodiment;

FIGS. 4A and 4B are sectional views for explaining the method of manufacturing a nonvolatile semiconductor memory device according to the second embodiment;

FIGS. 5A to 5E are sectional views for explaining the method of manufacturing a nonvolatile semiconductor memory device according to the second embodiment;

FIGS. 6A to 6E are sectional views for explaining the method of manufacturing a nonvolatile semiconductor memory device according to the second embodiment;

FIGS. 7A to 7E are sectional views for explaining the method of manufacturing a nonvolatile semiconductor memory device according to the second embodiment;

FIGS. 8A to 8E are sectional views for explaining the method of manufacturing a nonvolatile semiconductor memory device according to the second embodiment;

FIGS. 9A to 9E are sectional views for explaining the method of manufacturing a nonvolatile semiconductor memory device according to the second embodiment;

FIGS. 10A to 10E are sectional views for explaining the method of manufacturing a nonvolatile semiconductor memory device according to the second embodiment;

FIGS. 11A to 11E are sectional views for explaining the method of manufacturing a nonvolatile semiconductor memory device according to the second embodiment;

FIGS. 12A to 12D are sectional views for explaining a method of manufacturing a nonvolatile semiconductor memory device according to a third embodiment of the present invention;

FIGS. 13A to 13C are sectional views for explaining the method of manufacturing a nonvolatile semiconductor memory device according to the third embodiment;

FIGS. 14A to 14C are sectional views for explaining the method of manufacturing a nonvolatile semiconductor memory device according to the third embodiment;

FIGS. 15A to 15C are sectional views for explaining the method of manufacturing a nonvolatile semiconductor memory device according to the third embodiment;

FIGS. 16A to 16C are sectional views for explaining the method of manufacturing a nonvolatile semiconductor memory device according to the third embodiment;

FIGS. 17A and 17B are sectional views for explaining a method of manufacturing a nonvolatile semiconductor memory device according to a fourth embodiment of the present invention;

FIGS. 18A and 18B are sectional views for explaining the method of manufacturing a nonvolatile semiconductor memory device according to the fourth embodiment;

FIGS. 19A and 19B are sectional views for explaining the method of manufacturing a nonvolatile semiconductor memory device according to the fourth embodiment;

FIGS. 20A and 20B are sectional views for explaining the method of manufacturing a nonvolatile semiconductor memory device according to the fourth embodiment;

FIGS. 21A and 21B are sectional views for explaining the method of manufacturing a nonvolatile semiconductor memory device according to the fourth embodiment;

FIGS. 22A and 22B are sectional views of a schematic configuration of a nonvolatile semiconductor memory device according to a fifth embodiment of the present invention;

FIG. 23 is a perspective view of a schematic configuration of a nonvolatile semiconductor memory device according to a sixth embodiment of the present invention;

FIGS. 24A and 24B are sectional views for explaining a method of manufacturing a nonvolatile semiconductor memory device according to a seventh embodiment of the present invention;

FIGS. 25A and 25B are sectional views for explaining the method of manufacturing a nonvolatile semiconductor memory device according to the seventh embodiment;

FIGS. 26A and 26B are sectional views for explaining the method of manufacturing a nonvolatile semiconductor memory device according to the seventh embodiment;

FIGS. 27A to 27E are sectional views for explaining the method of manufacturing a nonvolatile semiconductor memory device according to the seventh embodiment;

FIGS. 28A to 28E are sectional views for explaining the method of manufacturing a nonvolatile semiconductor memory device according to the seventh embodiment;

FIGS. 29A to 29E are sectional views for explaining the method of manufacturing a nonvolatile semiconductor memory device according to the seventh embodiment;

FIGS. 30A to 30E are sectional views for explaining the method of manufacturing a nonvolatile semiconductor memory device according to the seventh embodiment; and

FIGS. 31A and 31B are sectional views of a schematic configuration of a nonvolatile semiconductor memory device according to an eighth embodiment of the present invention.

### DETAILED DESCRIPTION OF THE INVENTION

Exemplary embodiments of the present invention are explained in detail below with reference to the accompanying drawings. The present invention is not limited by the embodiments. For example, in the embodiments explained below, a NAND flash memory is explained as an example of a nonvolatile semiconductor memory device. However, the present invention can also be applied to a ferroelectric memory and the like besides the NAND flash memory.

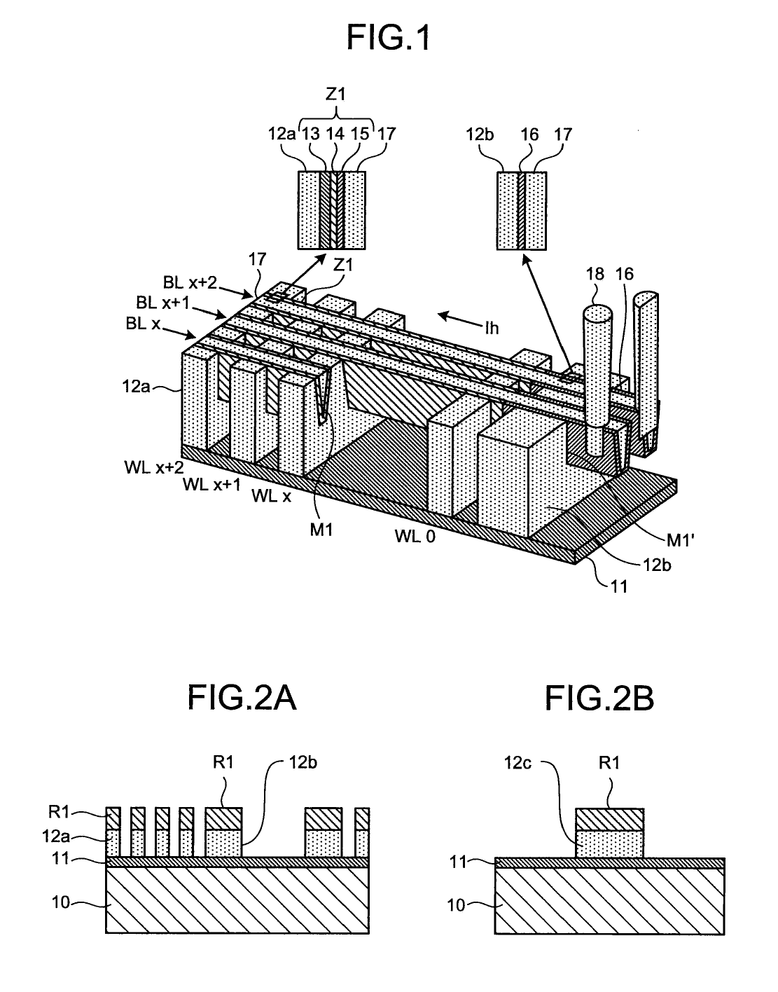

FIG. 1 is a perspective view of a schematic configuration of a nonvolatile semiconductor memory device according to a first embodiment of the present invention.

In FIG. 1, a plurality of fin-shaped control gate electrodes 12a and a fin-shaped select gate electrode 12b are formed on an insulating layer 11. The control gate electrodes 12a are arrayed on the insulating layer 11a predetermined space apart from one another. The control gate electrodes 12a can be used as, for example, word lines WL0 to WLx+2 in a NAND flash memory. As a material of the insulating layer 11, for example, an inorganic film such as a silicon oxide film can be used, a glass substrate or a ceramic substrate can be used, or an organic film of polyimide or the like can be used. As a material of the control gate electrodes 12a and the select gate electrode 12b, for example, polysilicon can be used.

Grooves M1 and M1′ are respectively formed in the control gate electrodes 12a and the select gate electrode 12b. A body layer 17 is embedded in the grooves M1 of the control gate electrodes 12a via a laminated insulating film Z1. The body layer 17 is embedded in the groove M1′ of the select electrode 12b via a gate insulating film 16. A plurality of the body layers 17 can be arrayed a predetermined space apart from one another to cross the control gate electrodes 12a and the select gate electrode 12b. When the body layers 17 are embedded in one control gate electrode 12a, a plurality of the grooves M1 can be formed in one control gate electrode 12a in a comb shape. The body layers 17 can be used as, for example, bit lines BLx to BLx+2 in the NAND flash memory (in FIG. 1, to show the structure of a section where the bit line BLx is embedded in the word line WLx, the bit line BLx is cut in the section of the word line WLx. However, the bit line BLx is also embedded in the work line WL0 and the select gate electrode 12b.)

As the laminated insulating film Z1, a laminated structure of a block layer 13, a charge storage layer 14, and a tunnel oxide film 15 can be used. As the charge storage layer 14, for example, a charge trap film including a silicon nitride film can be used or a floating gate electrode of polysilicon or the like can be used. The block layer 13 can prevent charges stored in the charge storage layer 14 from escaping. As the block layer 13, for example, a silicon oxide film can be used or oxide aluminum can be used.

In the body layers 17, channel regions embedded in the control gate electrodes 12a via the laminated insulating films Z1 can be provided and a channel region embedded in the select gate electrode 12b via the gate insulating film 16 can be provided. Source/drain layers can be formed in the body layers 17 by forming impurity diffusion layers on both the sides of the channel regions.

As the body layers 17, polysilicon layers can be used or continuous grain silicon layers can be used. When the continuous grain silicon layers are used as the body layers 17, it is desirable to grain-grow the continuous grain silicon layers in a direction in which an electric current Ih flows to the channel regions provided in the body layers 17.

The body layers 17 arranged to cross the control gate electrodes 12a and the select gate electrode 12b are extended a side of the select gate electrode 12b and connected to bit contacts 18.

Because the body layers 17 are embedded in the control gate electrodes 12a, the electric field of the channel regions provided in the body layers 17 can be controlled from both the sides thereof and an area of the charge storage layer 14 can be increased in the vertical direction. This makes it possible to improve controllability of a drain current by a gate electric field and increase the number of electrons that can be stored in the charge storage layer 14. Consequently, it is possible to improve the integration degree of the nonvolatile semiconductor memory device.

Further, because the body layers 17 are embedded in the control gate electrodes 12a, electric fields discharged from the body layers 17 in the horizontal direction can be blocked by the control gate electrodes 12a. This makes it possible to prevent the electric fields from interfering with each other between the body layers 17 adjacent to each other and reduce fluctuation in a threshold.

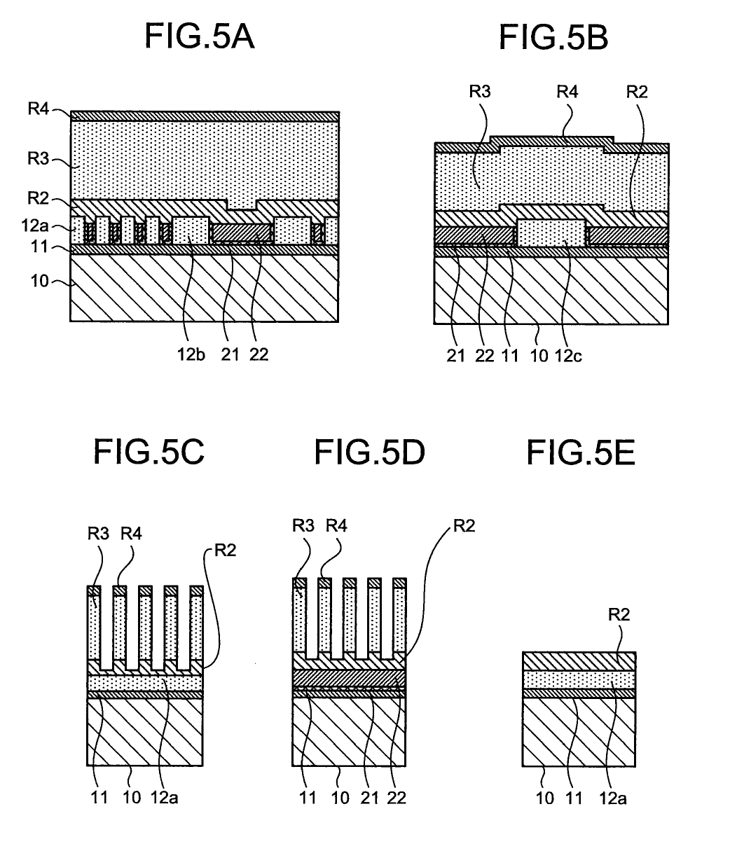

FIGS. 2A and 2B to FIGS. 11A to 11E are sectional views for explaining a method of manufacturing a nonvolatile semiconductor memory device according to a second embodiment of the present invention. FIGS. 2A, 3A, 4A, 5A, 6A, 7A, 8A, 9A, 10A, and 11A are sectional views of the section of the control gate electrodes 12a and select gate electrodes 12b shown in FIG. 1. FIGS. 2B, 3B, 4B, 5B, 6B, 7B, 8B, 9B, 10B, and 11B are sectional views of the section of a gate electrode 12c of a field effect transistor formed around a memory cell region shown in FIG. 1. FIGS. 5C, 6C, 7C, 8C, 9C, 10C, and 11C are sectional views of the section of the body layers 17 embedded in the control gate electrode 12a shown in FIG. 1. FIGS. 5D, 6D, 7D, 8D, 9D, 10D, and 11D are sectional views of the section of the bit contacts 18 connected to the body layers 17 shown in FIG. 1. FIGS. 5E, 6E, 7E, 8E, 9E, 10E, and 11E are sectional views of the section of a word contact 19 connected to the control gate electrode 12a shown in FIG. 1.

In FIGS. 2A and 2B, the insulating layer 11 is formed on a semiconductor substrate 10. A polysilicon layer is formed over the entire surface on the insulating layer 11 by a method such as the CVD. A mask pattern R1 corresponding to a planar shape of the control gate electrodes 12a and the select gate electrodes 12b shown in FIG. 1 and the gate electrode 12c is formed on the polysilicon layer by using the photolithography technology. The control gate electrodes 12a, the select gate electrodes 12b, and the gate electrode 12c are formed on the insulating layer 11 by dry-etching the polysilicon layer using the mask pattern R1 as an etching mask.

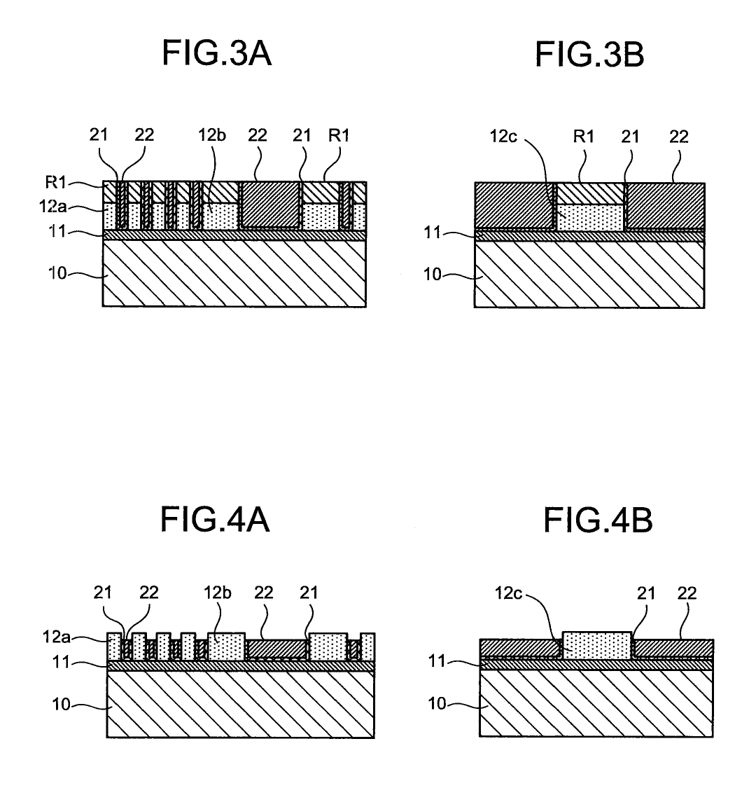

As shown in FIGS. 3A and 3B, device isolation insulating layers 21 and 22 are sequentially formed over the entire surface on the control gate electrodes 12a, the select gate electrodes 12b, and the gate electrode 12c to fill spaces among the control gate electrodes 12a, the select gate electrodes 12b, and the gate electrode 12c. As the device isolation insulating layers 21 and 22, for example, a silicon oxide film can be used. A laminated structure of a plurality of kinds of the device isolation insulating layers 21 and 22 can be used with step coverage, an inter-gap filling property, and the like taken into account.

The device isolation insulating layers 21 and 22 are planarized by thinning the same to expose the mask pattern R1 using a method such as the CMP.

As shown in FIGS. 4A and 4B, the mask pattern R1 on the control gate electrodes 12a, the select gate electrodes 12b, and the gate electrode 12c is removed by etching the mask pattern R1.

As shown in FIGS. 5A to 5E, a hard mask material R2 is formed over the entire surface on the control gate electrodes 12a, the select gate electrodes 12b, and the gate electrode 12c by a method such as the CVD. A mask pattern R3 for exposing the hard mask material R2 in the sections of the grooves M1 and M1′ shown in FIG. 1 and the word contact 19 is formed on the hard mask material R2 by using the photolithography technology. A reflection preventing film R4 can be formed on the mask pattern R3.

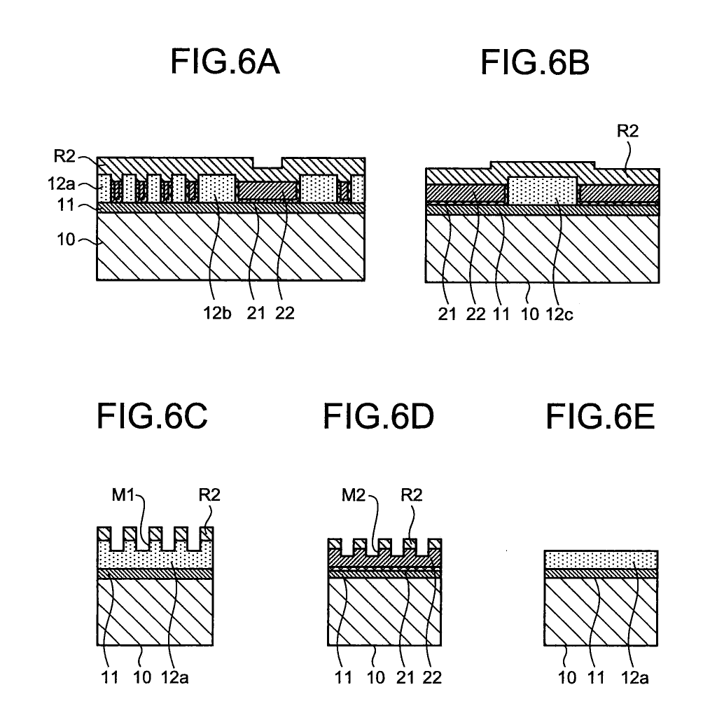

As shown in FIGS. 6A to 6E, the sections of the grooves M1 and M1′ shown in FIG. 1 and the word contact 19 are exposed from the hard mask material R2 by dry-etching the hard mask material R2 using the mask pattern R3 as an etching mask. After the mask pattern R3 and the reflection preventing film R4 are removed from the hard mask material R2, the grooves M1 and M1′ are respectively formed in the control gate electrodes 12a and the select gate electrodes 12b and grooves M2 are formed in the device isolation insulating layer 22 by half-etching the control gate electrodes 12a, the select gate electrodes 12b, and the device isolation insulating layer 22 using the hard mask material R2 as an etching mask.

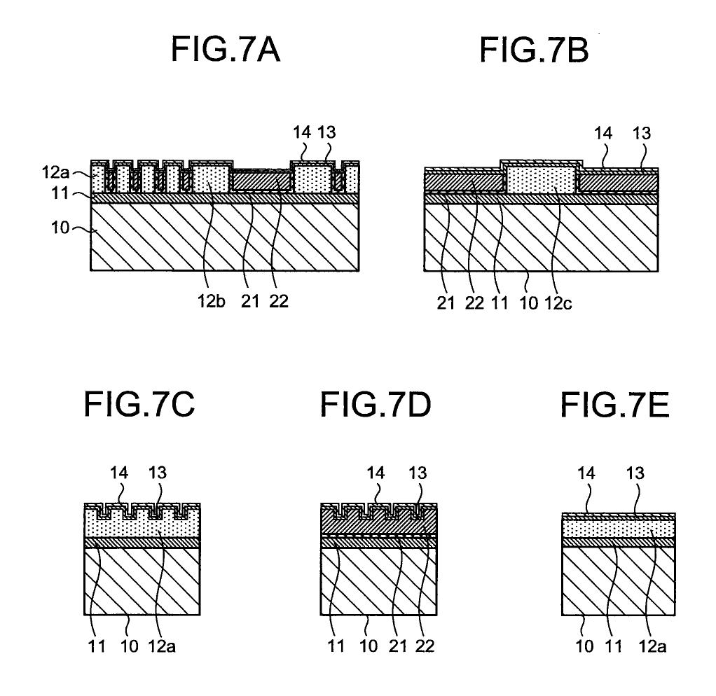

As shown in FIGS. 7A to 7E, the hard mask material R2 is removed. The block layer 13 and the charge storage layer 14 are sequentially laminated on the control gate electrodes 12a, the select gate electrodes 12b, and the device isolation insulating layer 22 to cover the surfaces of the grooves M1, M1′, and M2 by using a method such as the CVD or the sputtering.

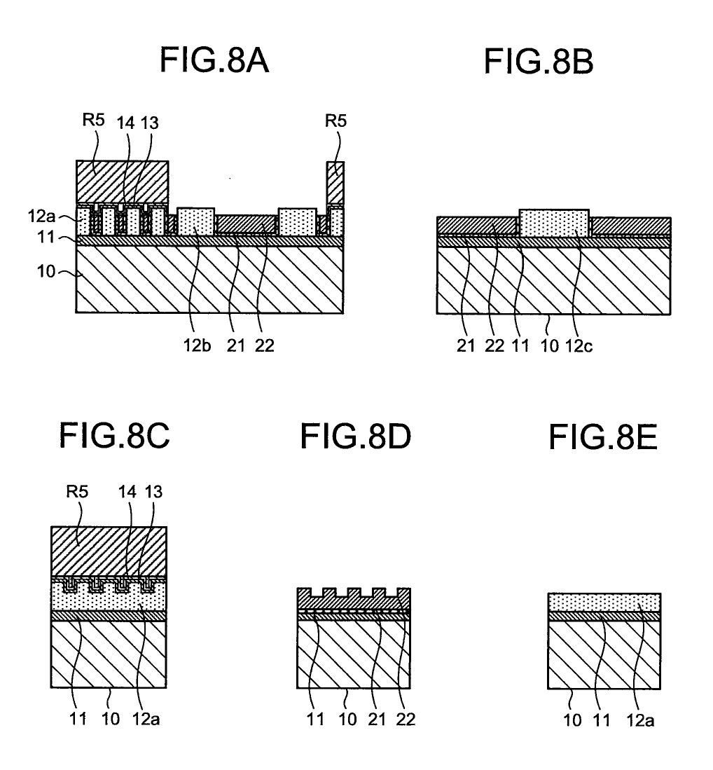

As shown in FIGS. 8A to 8E, a mask pattern R5 for covering the charge storage layer 14 on the control gate electrodes 12a shown in FIG. 1 and exposing the charge storage layer 14 in the sections of the select gate electrodes 12b, the gate electrode 12c, and the bit contacts 18 and the section of the word contact 19 is formed on the charge storage layer 14 by using the photolithography technology. The block layer 13 and the charge storage layer 14 are removed from the sections of the select gate electrodes 12b, the gate electrode 12c, and the bit contacts 18 and the section of the word contact 19 by dry-etching the block layer 13 and the charge storage layer 14 using the mask pattern R5 as an etching mask.

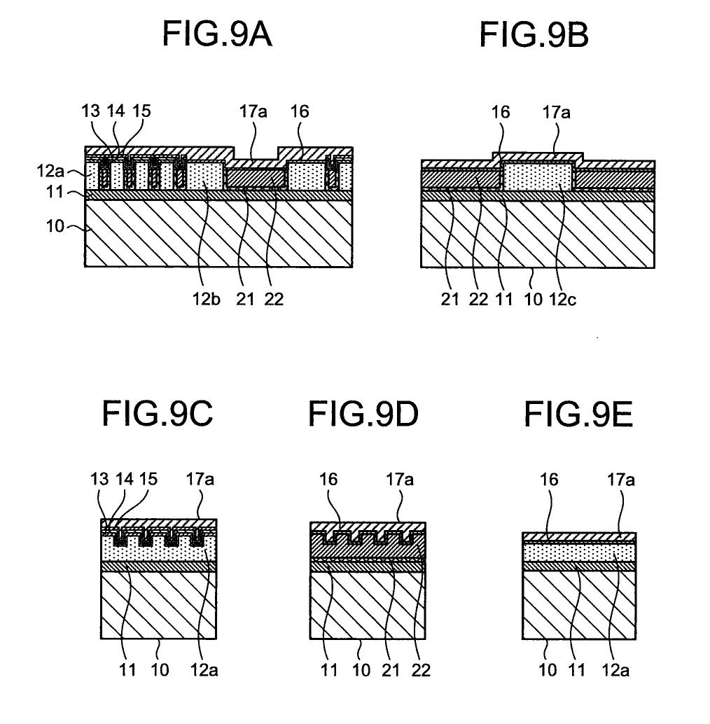

As shown in FIGS. 9A to 9E, the mask pattern R5 is removed from the charge storage layer 14. The tunnel oxide film 15 is formed on the charge storage layer 14 and the gate insulating film 16 is formed on the select gate electrodes 12b and the gate electrode 12c by using a method such as the CVD or the thermal oxidation. A polysilicon layer 17a is formed over the entire surface on the tunnel oxide film 15 and the gate insulating film 16 to fill the grooves M1, M1′, and M2 by using a method such as the CVD.

After the polysilicon layer 17a is formed over the entire surface on the tunnel oxide film 15 and the gate insulating film 16, the polysilicon layer 17a can be changed to a continuous grain silicon layer by performing thermal treatment of the polysilicon layer 17a using a method such as the laser anneal. It is desirable to grain-grow the continuous grain silicon layer along directions of the grooves M1, M1′, and M2.

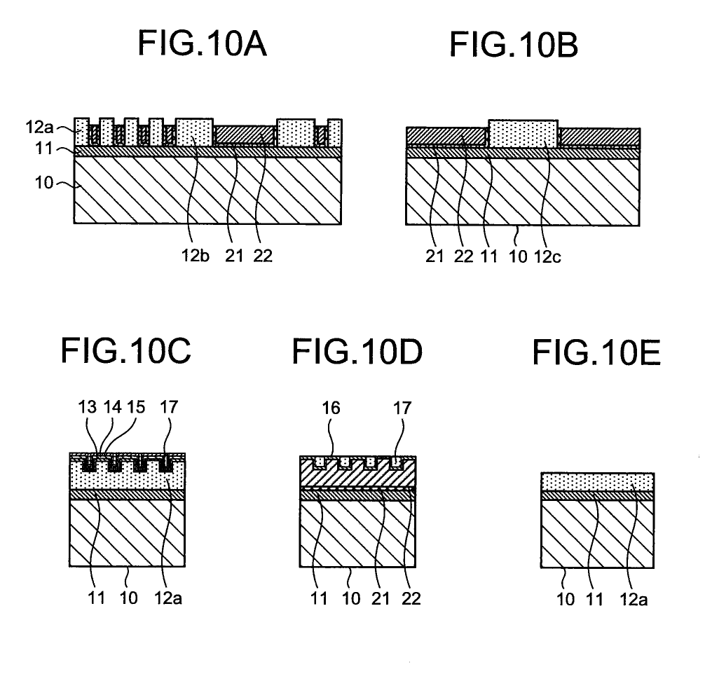

As shown in FIGS. 10A to 10E, the polysilicon layer 17a formed over the entire surface on the tunnel oxide film 15 and the gate insulating film 16 is thinned by using a method such as the CMP. The body layers 17 having the channel regions embedded in the control gate electrodes 12a are formed by removing the polysilicon layer 17a extruded from the grooves M1, M1′, and M2 onto the control gate electrodes 12a, the select gate electrodes 12b, and the gate electrode 12c. Source/drain layers arranged on both the sides of the channel regions are formed in the body layers 17 by selectively performing ion implantation of impurities in the body layers 17 according to necessity.

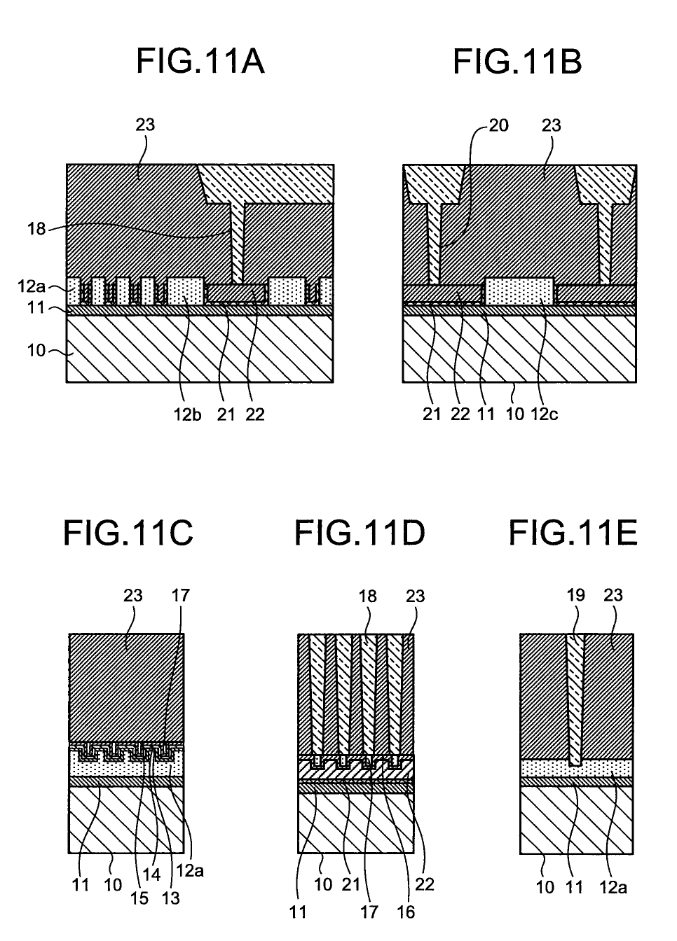

As shown in FIGS. 11A to 11E, an insulating layer 23 is formed over the entire surface on the body layers 17 by using a method such as the plasma CVD. As a material of the insulating layer 23, for example, a silicon oxide film can be used. The contact bits 18 connected to the body layers 17 are embedded in the insulating layer 23. At the same time, the word contact 19 connected to the control gate electrode 12a is embedded in the insulating layer 23. At the same time, source/drain contacts 20 connected to the source/drain layers of the field effect transistor formed around the memory cell region are embedded in the insulating layer 23.

Because the body layers 17 are arranged on the control gate electrodes 12a, the body layers 17 can be embedded in the control gate electrodes 12a by etching back the entire surface on the polysilicon layer 17a. This makes it possible to control the electric fields of the channel regions from both the sides of the channel regions without causing the control gate electrodes 12a to meander up and down along the sectional shape of the fins. This also makes it possible to improve controllability of a drain current by a gate electric field while reducing the difficult of processing of the control gate electrodes 12a.

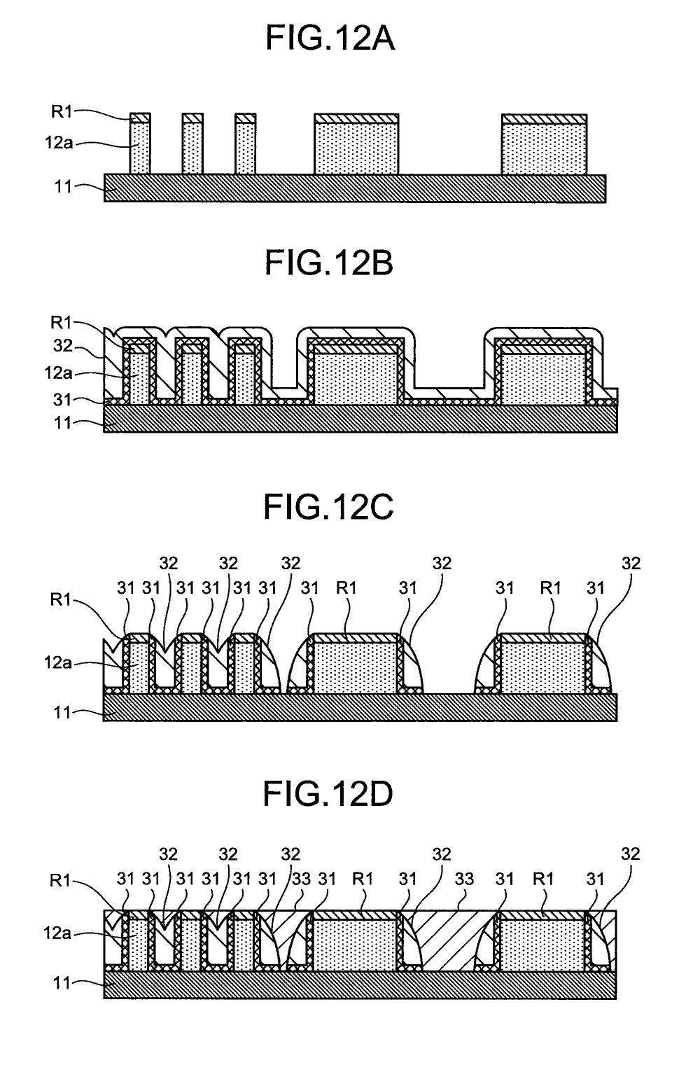

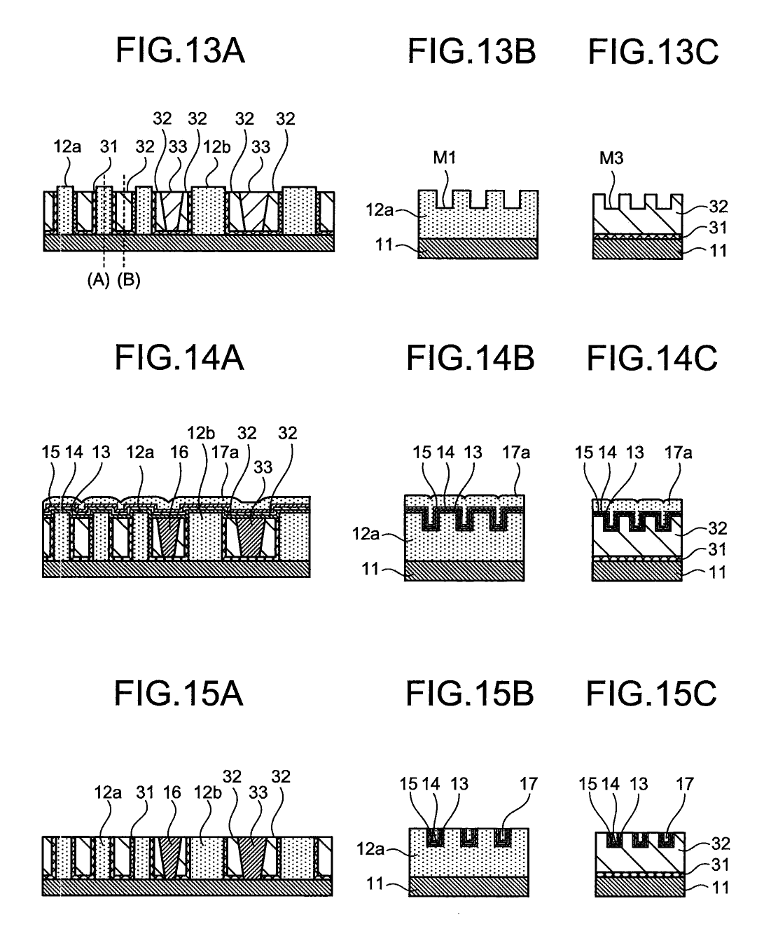

FIGS. 12A to 12D to FIGS. 16A to 16C are sectional views for explaining a method of manufacturing a nonvolatile semiconductor memory device according to a third embodiment of the present invention. FIGS. 12A to 12D and FIGS. 13A, 14A, 15A, and 16A are sectional views of the sections of the control gate electrodes 12a and the select gate electrodes 12b shown in FIG. 1. FIGS. 13B, 14B, 15B, and 16B are sectional views of a section (A) shown in FIG. 13A. FIGS. 13C, 14C, 15C, and 16C are sectional views of a section (B) shown in FIG. 13A.

In FIG. 12A, the control gate electrodes 12a and the select gate electrodes 12b are formed on the insulating layer 11 in the same manner as the method shown in FIGS. 2A and 2B. As the mask pattern R1, for example, a silicon oxide film can be used.

As shown in FIG. 12B, an insulating layer 31 and a sacrificial layer 32 are sequentially formed over the entire surface on the control gate electrodes 12a and the select gate electrodes 12b to fill spaces among the control gate electrodes 12a by using a method such as the CVD. As the insulating layer 31, for example, a silicon oxide film can be used. As the sacrificial layer 32, for example, a silicon nitride film can be used.

As shown in FIG. 12C, the mask pattern R1 is exposed while keeping the spaces among the control gate electrodes 12a filled with the sacrificial layer 32 by etching back the insulating layer 31 and the sacrificial layer 32 with anisotropic etching such as the RIE.

As shown in FIG. 12D, a device isolation insulating layer 33 is sequentially formed over the entire surface on the control gate electrodes 12a and the select gate electrodes 12b to fill the periphery of the select gate electrodes 12b by using a method such as the CVD. As the device isolation insulating layer 33, for example, a silicon oxide film can be used. The device isolation insulating layer 33 is planarized by thinning the same to expose the mask pattern R1 using a method such as the CMP.

As shown in FIGS. 13A to 13C, the mask pattern R1 on the control electrodes 12a is removed while keeping the spaces among the control gate electrodes 12a filled with the sacrificial layer 32 by etching back the sacrificial layer 32 with anisotropic etching such as the RIE. The grooves M1 are formed in the control gate electrodes 12a and the grooves M3 are formed in the sacrificial layer 32 by using a method same as that shown in FIGS. 5A to 5E and FIGS. 6A to 6E.

As shown in FIGS. 14A to 14C, the block layer 13 and the charge storage layer 14 are sequentially laminated on the control gate electrodes 12a and the select gate electrodes 12b to cover the surfaces of the grooves M1 and M3 by using a method same as the method shown in FIGS. 7A to 7E to FIGS. 9A to 9E. After the block layer 13 and the charge storage layer 14 on the select gate electrodes 12b are removed, the tunnel oxide film 15 is formed on the charge storage layer 14 and the gate insulating film 16 is formed on the select gate electrodes 12b. The polysilicon layer 17a is formed over the entire surface on the tunnel oxide film 15 and the gate insulating film 16 to fill the grooves M1 and M3.

As shown in FIGS. 15A to 15C, the body layers 17 having the channel regions embedded in the control gate electrodes 12a are formed and the sacrificial layer 32 is exposed by thinning the polysilicon layer 17a formed over the entire surface on the tunnel oxide film 15 and the gate insulating film 16 and removing the polysilicon layer 17a extruded from the grooves M1 and M3 onto the control gate electrodes 12a and the select gate electrodes 12b using a method such as the CMP.

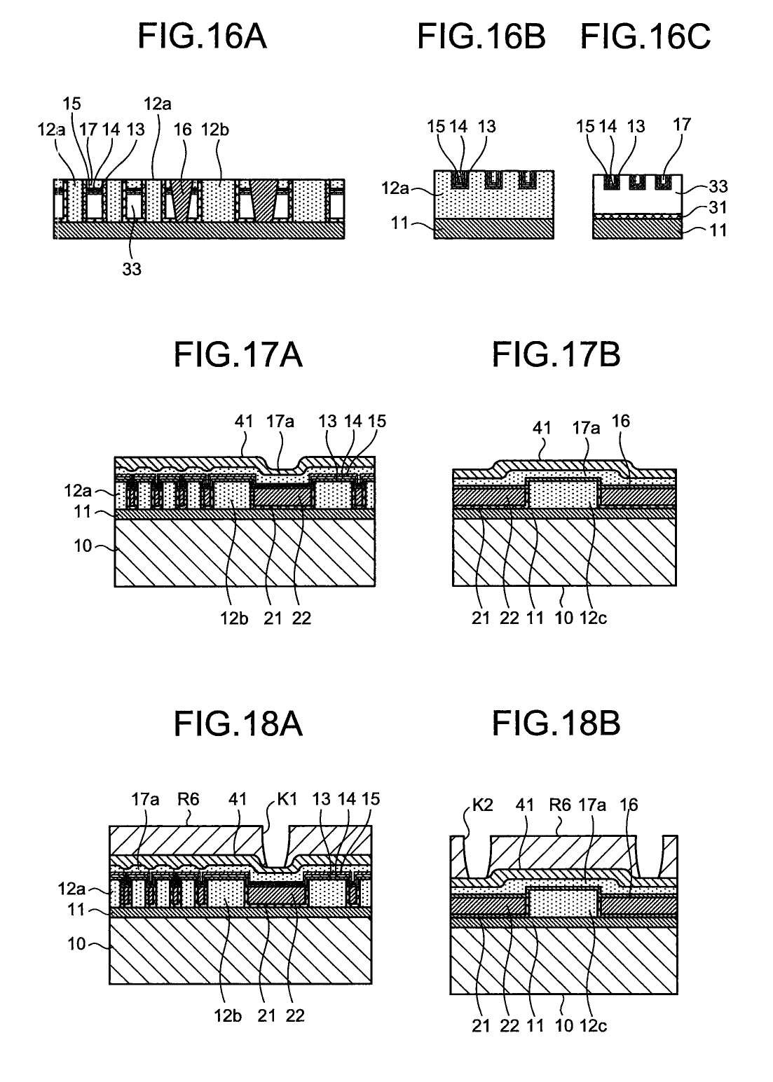

As shown in FIGS. 16A to 16C, hollow sections 33 are formed under the body layers 17 among the control gate electrodes 12a with the body layers 17 embedded in the control gate electrodes 12a by removing the sacrificial layer 32 among the control gate electrodes 12a using a method such as the wet etching. For example, when the sacrificial layer 32 is a silicon nitride film, hot phosphoric acid can be used as a chemical for the wet etching. The polysilicon layer 17a is changed to a continuous grain silicon layer by performing thermal treatment of the body layers 17 with a method such as the laser anneal.

Because the hollow sections 33 are formed under the body layers 17 among the control gate electrodes 12a, the thermal conductivity of the body layers 17 on the hollow sections 33 can be set lower than the thermal conductivity of the body layers 17 on the control gate electrodes 12a. The thermal conductivity of the body layers 17 can be changed in the directions of the grooves M1 and M3. This makes it possible to generate a temperature gradient of the body layers 17 in the directions of the grooves M1 and M3 when the thermal treatment of the body layers 17 is performed. Because grain growth is performed from a high temperature side to a low temperature side, the continuous grain silicon layer can be grain-grown along the directions of the grooves M1 and M3.

Source/drain layers arranged on both the sides of the channel regions are formed in the body layers 17 by selectively performing ion implantation of impurities in the body layers 17 according to necessity.

The body layers 17 are arranged from the grooves M1 of the control gate electrodes 12a to the grooves M3 of the sacrificial layer 32. This makes it possible to form the hollow sections 33 under the body layers 17 among the control gate electrodes 12a and change the thermal conductivity of the body layers 17 in the directions of the grooves M1 and M3 while suppressing complication of a manufacturing process.

FIGS. 17A and 17B to FIGS. 21A and 21B are sectional views for explaining a method of manufacturing a nonvolatile semiconductor memory device according to a fourth embodiment of the present invention. FIGS. 17A, 18A, 19A, 20A, and 21A are sectional views of the sections of the control gate electrodes 12a and the select gate electrodes 12b shown in FIG. 1. FIGS. 17B, 18B, 19B, 20B, and 21B are sectional views of the section of the gate electrode 12c of the field effect transistor formed around the memory cell region shown in FIG. 1.

In FIGS. 17A and 17B, the polysilicon layer 17a is formed over the entire surface on the tunnel oxide film 15 and the gate insulating film 16 by using a method same as the method shown in FIGS. 2A and 2B to FIGS. 9A to 9E. An insulating layer 41 is laminated on the polysilicon layer 17a by using a method such as the CVD. As the insulating layer 41, for example, a silicon nitride film can be used.

As shown in FIGS. 18A and 18B, a mask pattern R6 in which openings K1 and K2 are formed is formed on the insulating layer 41 by using the photolithography technology. It is desirable to arrange the openings K1 and K2 to avoid the memory cell region. For example, the opening K1 can be arranged in the position of the bit contact 18 shown in FIG. 11A and the openings K2 can be arranged in the positions of the source/drain contacts 20 shown in FIG. 11B.

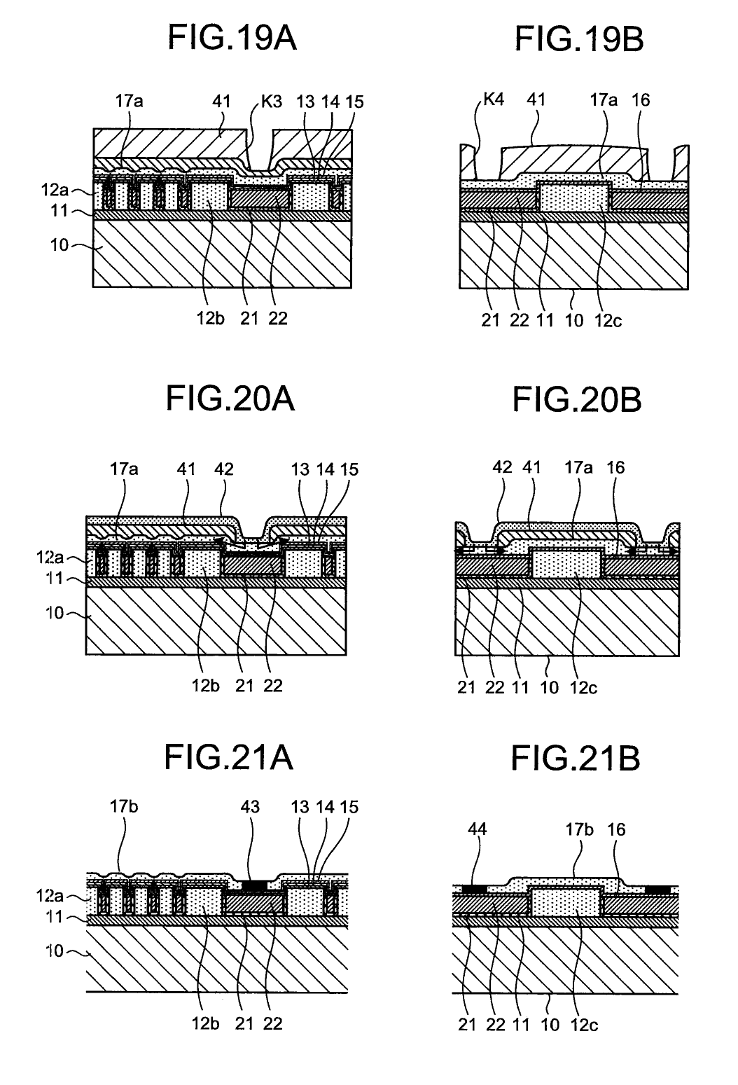

As shown in FIGS. 19A and 19B, openings K3 and K4 arranged to correspond to the positions of the openings K1 and K2 are formed in the insulating film 41 by dry-etching the insulating layer 41 using the mask pattern R6 as an etching mask.

As shown in FIGS. 20A and 20B, a crystalline nucleus layer 42 set in contact with the polysilicon layer 17a via the openings K3 and K4 is formed on the insulating layer 41 by using a method such as the sputtering. As the crystalline nucleus layer 42, for example, a metal film of Ni, Ge, or the like can be used. The polysilicon layer 17a is changed to a continuous grain silicon layer 17b by performing thermal treatment of the polysilicon layer 17a with a method such as the laser anneal.

Grain growth of the polysilicon layer 17a is started with the crystalline nucleus layer 42 as a starting point. Therefore, the polysilicon layer 17a can be grain-grown along the directions of the grooves M1 and M1′ shown in FIG. 1. When the thermal treatment of the polysilicon layer 17a is performed, the crystalline nucleus layer 42 and the polysilicon layer 17a react with each other. As shown in FIGS. 21A and 21B, silicide layers 43 and 44 are formed in contact sections between the crystalline nucleus layer 42 and the polysilicon layer 17a.

As shown in FIGS. 21A and 21B, when the continuous grain silicon layer 17b is formed from the polysilicon layer 17a, the crystalline nucleus layer 42, which does not react with the polysilicon layer 17a, is removed from the insulating layer 41 by a method such as the wet etching.

The body layers 17 having the channel regions embedded in the control gate electrodes 12a are formed by removing the continuous grain silicon layer 17b extruded from the grooves M1 and M1′ onto the control gate electrodes 12a and the select gate electrodes 12b using a method same as the method shown in FIGS. 10A to 10E and FIGS. 11A to 11E. After the insulating layer 23 is formed over the entire surface on the body layers 17, the bit contacts 18, the word contact 19, and the source/drain contacts 20 are embedded in the insulating layer 23.

Because the control gate electrodes 12a are arranged under the body layers 17, even when the control gate electrodes 12a are present, the crystalline nucleus layer 42 can be selectively set in contact with the body layers 17. The non-reacting crystalline nucleus layer 42 can be easily removed. This makes it possible to grain-grow the polysilicon layer 17a in the directions of the grooves M1 and M3 while suppressing complication of a manufacturing process.

The contact sections between the body layers 17 and the crystalline nucleus layer 42 are arranged in contact regions of the bit contacts 18, the word contact 19, the source/drain contacts 20, and the like. This makes it possible to form the body layers 17 in the continuous grain silicon layer 17b and reduce contact resistance without deteriorating the switching characteristic of the memory cell region.

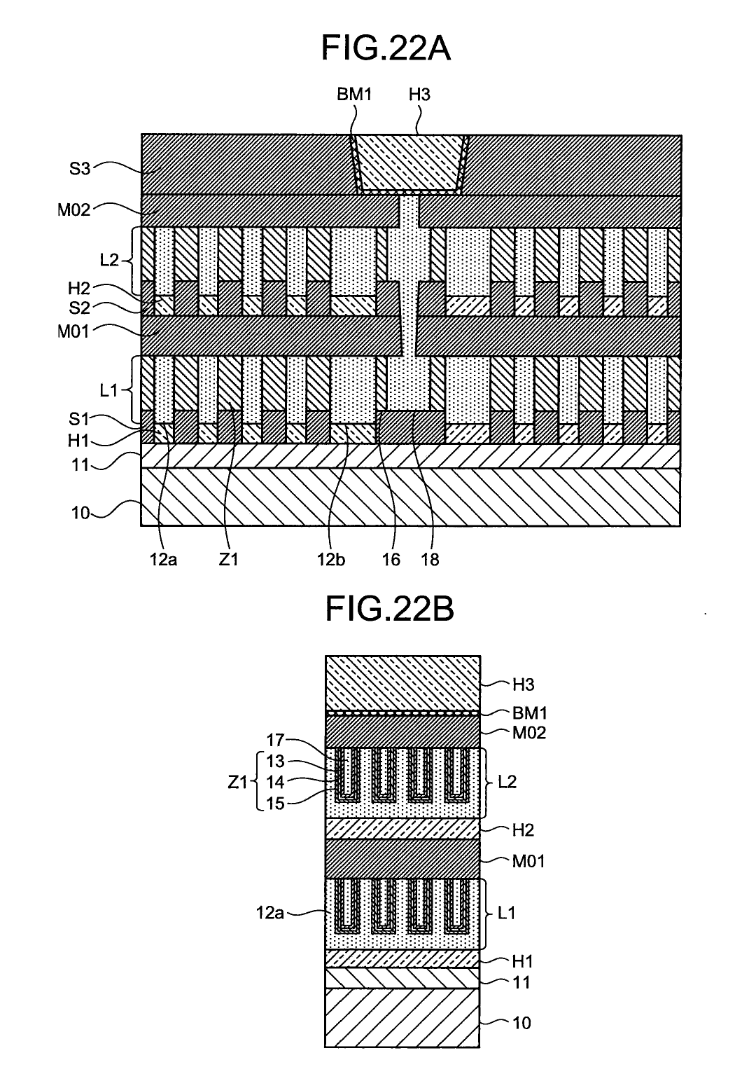

FIGS. 22A and 22B are sectional views of a schematic configuration of a nonvolatile semiconductor memory device according to a fifth embodiment of the present invention. FIG. 22A is a sectional view of the sections of the control gate electrodes 12a and the select gate electrodes 12b shown in FIG. 1. FIG. 22B is a sectional view of the section of the body layers 17 embedded in the control gate electrodes 12a shown in FIG. 1.

An interlayer insulating film M01 is formed between memory cell array layers L1 and L2. An interlayer insulating film M02 is formed on the memory cell array layer L2. A wiring layer H3 connected to the bit contacts 18 is formed on the interlayer insulating film M02. The wiring layer H3 is embedded in an insulating layer S3 via a barrier metal film BM1. As the wiring layers H1 and H2, for example, a metal wire of Al, Cu, or the like can be used. As the interlayer insulating films M01 and M02, the device isolation insulating layers S1 and S2, and the insulating layer S3, for example, a silicon oxide film can be used. As the barrier metal film BM1, for example, a TiN film can be used.

The memory cell array layers L1 and L2 are laminated in the vertical direction. This makes it possible to increase an integration degree of the nonvolatile semiconductor memory device without microminiaturizing memory cells and increase a memory capacity while suppressing deterioration in characteristics of the nonvolatile semiconductor memory device.

In the embodiment shown in FIGS. 22A and 22B, the method of laminating the two memory cell array layers L1 and L2 on the insulating layer 11 is explained. However, three or more memory cell array layers can be laminated.

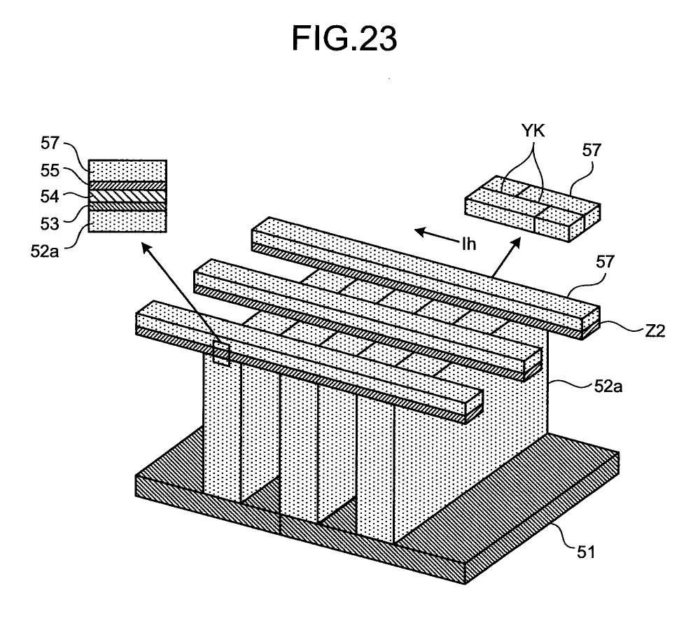

FIG. 23 is a perspective view of a schematic configuration of a nonvolatile semiconductor memory device according to a sixth embodiment of the present invention.

In FIG. 23, a plurality of control gate electrodes 52a are formed on an insulating layer 51. The control gate electrodes 52a are arrayed on the insulating layer 51a predetermined space apart from one another. The control gate electrodes 52a can be used as, for example, word lines in a NAND flash memory. As a material of the insulating layer 51, for example, an inorganic film such as a silicon oxide film can be used, a glass substrate or a ceramic substrate can be used, or an organic film of polyimide or the like can be used. As a material of the control gate electrodes 52a, for example, polysilicon can be used.

A body layer 57 is arranged on the control gate electrodes 52a via a laminated insulating film Z2. A plurality of the body layers 57 can be arrayed a predetermined space apart from one another to cross the control gate electrodes 52a. The body layers 57 can be used as, for example, bit lines in the NAND flash memory.

As the laminated insulating film Z2, a laminated structure of a block layer 53, a charge storage layer 54, and a tunnel oxide film 55 can be used. As the charge storage layer 54, for example, a charge trap including a silicon nitride film can be used or a floating gate electrode of polysilicon can be used. The block layer 53 can prevent charges stored in the charge storage layer 54 from escaping. As the block layer 53, for example, a silicon oxide film can be used or aluminum oxide can be used.

Channel regions arranged on the control gate electrodes 52a can be provided in the body layers 57. Source/drain layers can be formed in the body layers 57 by forming impurity diffusion layers on both the sides of the channel regions.

The body layers 57 can be configured by using a continuous grain silicon layer grain-grown in a direction in which the electric current Ih flows to the channel regions by being grain-grown in a direction crossing the control gate electrodes 52a. Because the continuous grain silicon layer is grain-grown in the direction in which the electric current Ih flows to the channel regions, the density of a grain boundary YK in a gate length direction can be set smaller than the density of the grain boundary YK in a gate width direction. Therefore, electron mobility can be increased by about one digit and an ON current can be increased compared with those obtained when the body layers 57 are formed of polysilicon. Therefore, operation speed can be improved.

Because the control gate electrodes 52a are arranged under the body layers 57, even when the control gate electrodes 52a are present, it is possible to grain-grow the body layers 57 in the gate length direction and suppress a fall in the operation speed.

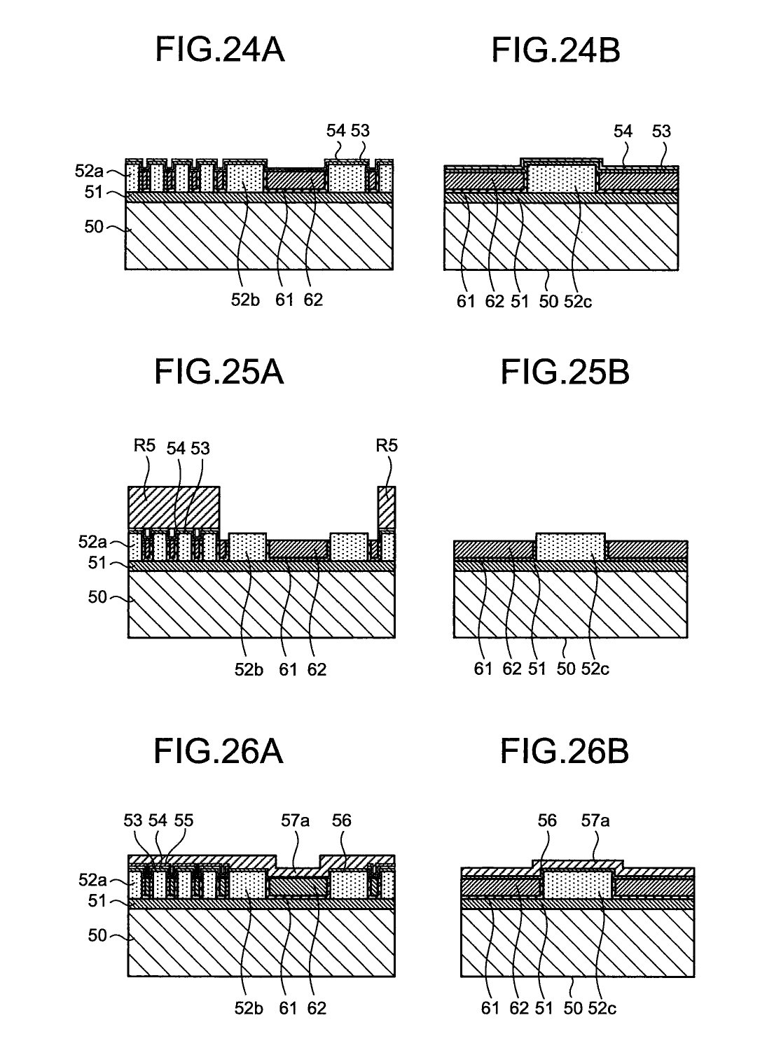

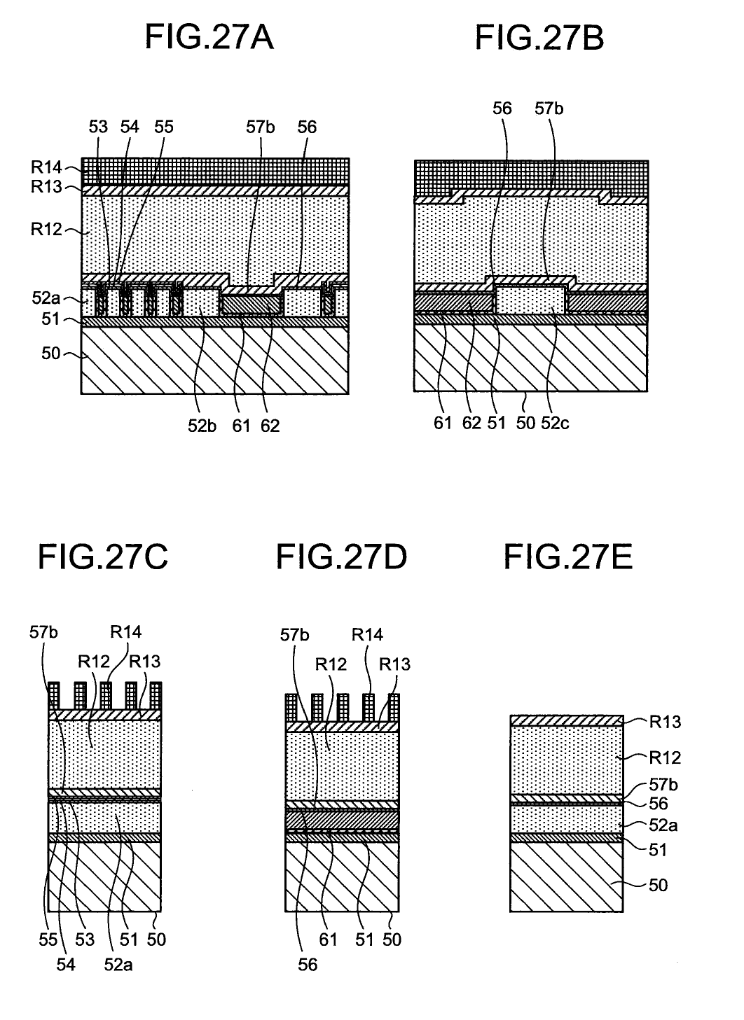

FIGS. 24A and 24B to FIGS. 30A to 30E are sectional views for explaining a method of manufacturing a nonvolatile semiconductor memory device according to a seventh embodiment of the present invention. FIGS. 24A, 25A, 26A, 27A, 28A, 29A, and 30A are sectional views of the sections of the control gate electrodes 52a shown in FIG. 23 and select gate electrodes 52b. FIGS. 24B, 25B, 26B, 27B, 28B, 29B, and 30B are sectional views of the section of a gate electrode 52c of a field effect transistor formed around a memory cell region shown in FIG. 23. FIGS. 27C, 28C, 29C, and 30C are sectional views of the section of the body layer 57 on the control gate electrode 52a shown in FIG. 23. FIGS. 27D, 28D, 29D, and 30D are sectional views of the section of bit contacts 58 connected to the body layer 57 shown in FIG. 23. FIGS. 27E, 28E, 29E, and 30E are sectional views of the section of a word contact 59 connected to the control gate electrode 52a shown in FIG. 23.

In FIGS. 24A and 24B, the insulating layer 51 is formed on a semiconductor substrate 50. The control gate electrodes 52a, the select gate electrodes 52b, and the gate electrode 52c are formed on the insulating layer 51. Thereafter, device isolation insulating layers 61 and 62 are sequentially formed to fill spaces among the control gate electrodes 52a, the select gate electrodes 52b, and the gate electrode 52c.

A block layer 53 and a charge storage layer 54 are sequentially laminated over the entire surface on the control gate electrodes 52a, the select gate electrodes 52b, and the device isolation insulating layer 62 by using a method such as the CVD or the sputtering.

As shown in FIGS. 25A and 25B, a mask pattern R5 for covering the charge storage layer 54 on the control gate electrodes 52a shown in FIG. 23 and exposing the charge storage layer 54 in the sections of the select gate electrodes 52b, the gate electrode 52c, and the bit contacts 58 and the section of the word contact 59 is formed on the charge storage layer 54 by using the photolithography technology. The block layer 53 and the charge storage layer 54 are removed from the sections of the select gate electrodes 52b, the gate electrode 52c, and the bit contacts 58 and the section of the word contact 59 by dry-etching the block layer 53 and the charge storage layer 54 using the mask pattern R5 as an etching mask.

As shown in FIGS. 26A and 26B, the mask pattern R5 is removed from the charge storage layer 54. A tunnel oxide film 55 is formed on the charge storage layer 54 and a gate insulating film 56 is formed on the select gate electrodes 52b and the gate electrode 52c by using a method such as the CVD or the thermal oxidation. A polysilicon layer 57a is formed over the entire surface on the tunnel oxide film 55 and the gate insulating film 56 by using a method such as the CVD.

After the polysilicon layer 57a is formed over the entire surface on the tunnel oxide film 55 and the gate insulating film 56, the polysilicon layer 57a is changed to a continuous grain silicon layer 57b shown in FIGS. 27A to 27E, which is grain-grown along a gate length direction, by performing thermal treatment of the polysilicon layer 57a with a method such as the laser anneal.

As shown in FIGS. 27A to 27E, a hard mask material R12 is formed over the entire surface on the control gate electrodes 52a, the select gate electrodes 52b, and the gate electrode 52c by a method such as the CVD. A reflection preventing film R13 can be formed on the hard mask material R12. A mask pattern R14 for exposing the hard mask material R12 in the sections among the body layers 57 shown in FIG. 23 and the section of the word contact 59 is formed on the hard mask material R12 by using the photolithography technology.

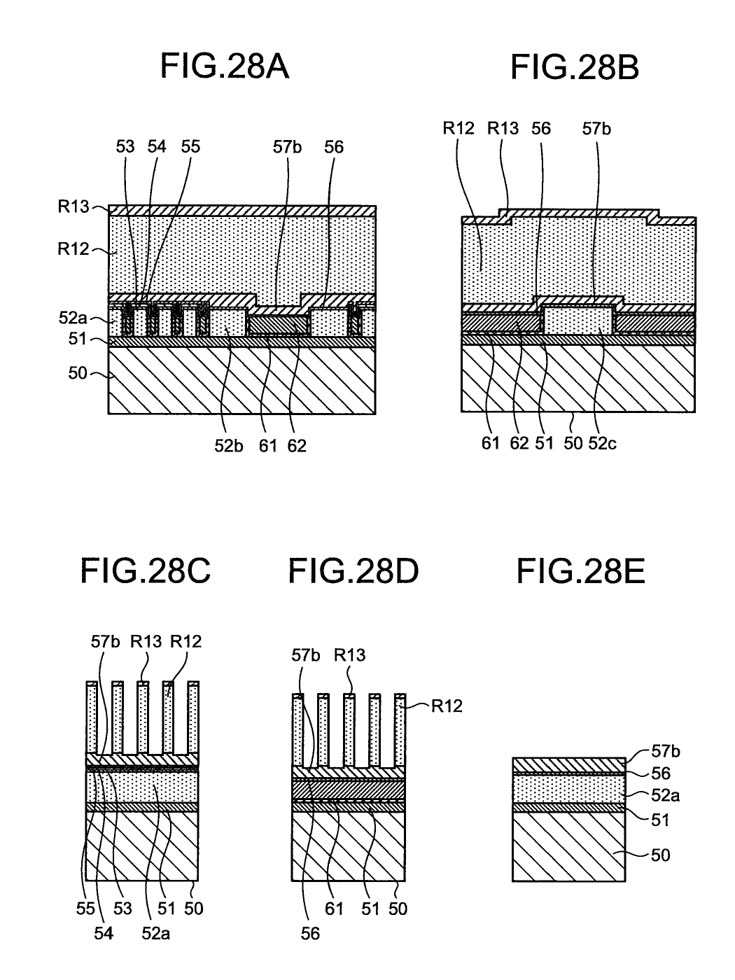

As shown in FIGS. 28A to 28E, the sections among the body layers 57 shown in FIG. 23 and the section of the word contact 59 are exposed from the hard mask material R12 and the reflection preventing film R13 by dry-etching the hard mask material R12 and the reflection preventing film R13 using the mask pattern R14 as an etching mask.

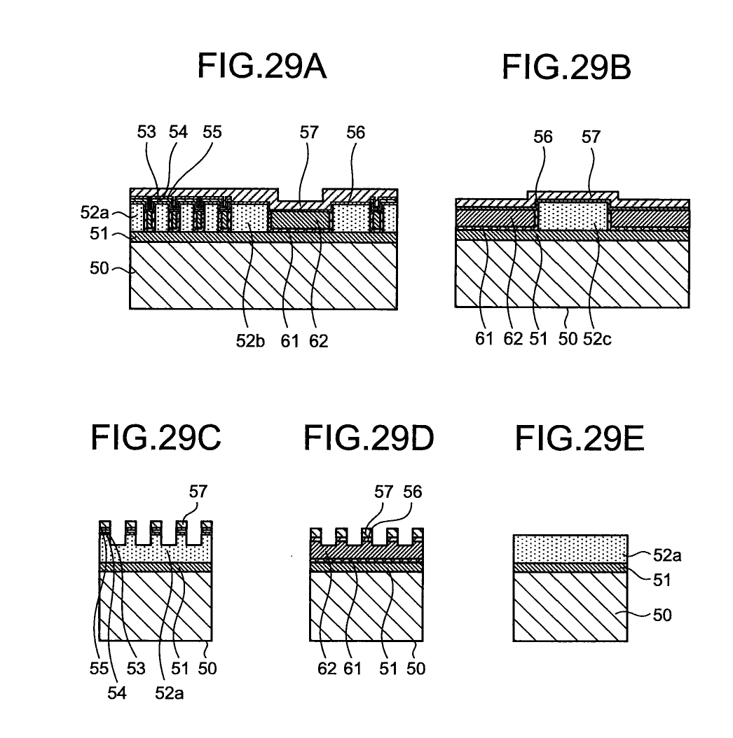

As shown in FIGS. 29A to 29E, after the mask pattern R14 is removed from the reflection preventing film R13, the body layers 57 arranged on the control gate electrodes 52a and the select gate electrodes 52b are formed by etching the continuous grain silicon layer 57b, the block layer 53, the charge storage layer 54, the tunnel oxide film 55, and the gate insulating film 56 using the hard mask material R12 as an etching mask. The block layer 53, the charge storage layer 54, the tunnel oxide film 55, and the gate insulating film 56 among the body layers 57 are removed by the etching.

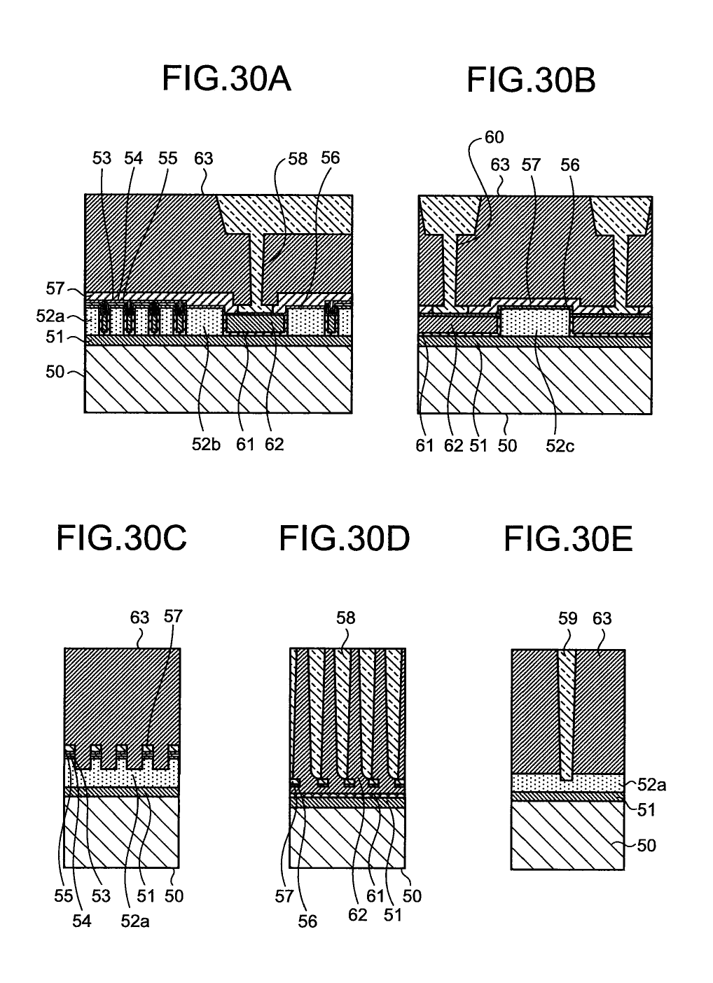

As shown in FIGS. 30A to 30E, an insulating layer 63 is formed over the entire surface on the body layers 57 by using a method such as the plasma CVD. As a material of the insulating layer 63, for example, a silicon oxide film can be used. The contact bits connected to the body layers 57 are embedded in the insulating layer 63. At the same time, the word contact 59 connected to the control gate electrodes 52a is embedded in the insulating layer 63. At the same time, source/drain contacts 60 connected to a source/drain layer of a field effect transistor formed around the memory cell region are embedded in the insulating layer 63.

Because the control gate electrodes 52a are arranged under the body layers 57, even when the control gate electrodes 52a are present, it is possible to configure the body layers 57 using the continuous grain silicon layer 57b grain-grown in the gate length direction while suppressing complication of a manufacturing process.

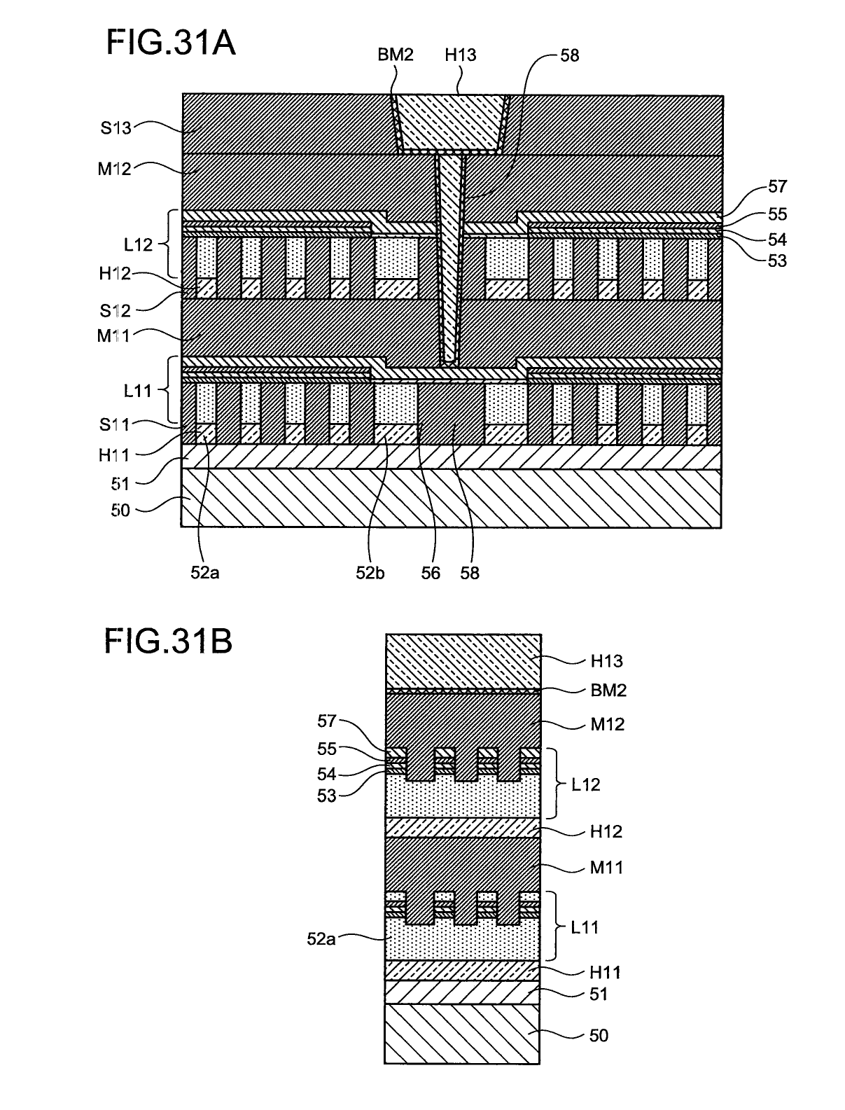

FIGS. 31A and 31B are sectional views of a schematic configuration of a nonvolatile semiconductor memory device according to an eighth embodiment of the present invention. FIG. 31A is a sectional view of the sections of the control gate electrodes 52a shown in FIG. 23 and the select gate electrodes 52b. FIG. 31B is a sectional view of the section of the body layers 57 on the control gate electrode 52a shown in FIG. 23.

In FIGS. 31A and 31B, memory cell array layers L11 and L12 are laminated in the vertical direction on the insulating layer 51 on the semiconductor substrate 50. As the memory cell array layers L11 and L12, the configuration shown in FIG. 23 can be used. In the memory cell array layers L11 and L12, wiring layers H11 and H12 are respectively formed under the control gate electrodes 52a and the select gate electrodes 52b along the control gate electrodes 52a and the select gate electrodes 52b. The control gate electrodes 52a, the select gate electrodes 52b, and the wiring layers H11 and H12 of the memory cell array layers L11 and L12 are separated by device isolation insulating layers S11 and S12.

An interlayer insulating film M11 is formed between the memory cell array layers L11 and L12. An interlayer insulating film M12 is formed on the memory cell array layer L12. A wiring layer H13 connected to the bit contacts 58 is formed on the interlayer insulating film M12. The wiring layer H13 is embedded in an insulating layer S13 via a barrier metal film BM2. As the wiring layers H11 and H12, for example, metal wires of Al, Cu, or the like can be used. As the interlayer insulating films M11 and M12, the device isolation insulating layers S11 and S12, and the insulating layer S13, for example, a silicon oxide film can be used. As the barrier metal film BM2, for example, a TiN film can be used.

The body layers 57 are formed by using the continuous grain silicon layer 57b grain-grown in the gate length direction. Therefore, it is possible to laminate the memory cell array layers L11 and L12 in the vertical direction while making it possible to increase electron mobility by about one digit compared with that obtained when the body layers 57 are formed by using the polysilicon layer 57a. This makes it possible to increase an integration degree of the nonvolatile semiconductor memory device without microminiaturizing memory cells, suppress a fall in operation speed, and increase a memory capacity while suppressing deterioration in characteristics of the nonvolatile semiconductor memory device.

In the embodiment shown in FIGS. 31A and 31B, the method of laminating the two memory cell array layers L11 and L12 on the insulating layer 51 is explained. However, three or more memory cell array layers can be laminated.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor memory device comprising:
fin-shaped control gate electrodes formed on an insulating layer; and
a body layer having a channel region arranged to cross the control gate electrodes and embedded in the control gate electrodes sequentially via a first insulating layer, a charge storage layer, and a second insulating layer.

2. The nonvolatile semiconductor memory device according to claim 1, wherein the body layer is continuous grain silicon grain-grown in a direction crossing the control gate electrodes.

3. The nonvolatile semiconductor memory device according to claim 2, further comprising a silicide layer arranged in an area in a part of the body layer and formed by reacting with a crystalline nucleus to be grain-grown.

4. The nonvolatile semiconductor memory device according to claim 3, wherein the crystalline nucleus is Ni.

5. The nonvolatile semiconductor memory device according to claim 2, further comprising:
device isolation insulating layers formed on both sides of the body layer between the control gate electrodes; and
a hollow section formed under the body layer between the control gate electrodes.

6. The nonvolatile semiconductor memory device according to claim 1, further comprising a select gate electrode arranged in parallel to the control gate electrodes on the insulating layer, the body layer being embedded in the select gate electrode via a gate insulating film.

7. The nonvolatile semiconductor memory device according to claim 1, wherein a plurality of memory cell array layers including the control gate electrodes, the first insulating layer, the charge storage layer, the second insulating layer, and the body layer are formed.

8. The nonvolatile semiconductor memory device according to claim 7, further comprising a wiring layer arranged under the control gate electrodes to cross the body layer.

9. The nonvolatile semiconductor memory device according to claim 1, wherein a plurality of grooves in which a plurality of the body layers are respectively embedded are formed in a comb shape in the control gate electrodes.

10. The nonvolatile semiconductor memory device according to claim 1, wherein
the control gate electrodes are used as word lines in a NAND flash memory, and
the body layer is used as a bit line in the NAND flash memory.

11. The nonvolatile semiconductor memory device according to claim 1, wherein the charge storage layer is a charge trap film including a silicon nitride film.

12. A nonvolatile semiconductor memory device comprising:
control gate electrodes formed on an insulating layer; and
a body layer formed of continuous grain silicon grain-grown in a direction crossing the control gate electrodes and arranged on the control gate electrodes to cross the control gate electrodes sequentially via a first insulating layer, a charge storage layer, and a second insulating layer.

13. The nonvolatile semiconductor memory device according to claim 12, wherein a plurality of memory cell array layers including the control gate electrodes, the first insulating layer, the charge storage layer, the second insulating layer, and the body layer are formed.

14. The nonvolatile semiconductor memory device according to claim 12, wherein
the control gate electrodes are used as word lines in a NAND flash memory, and
the body layer is used as a bit line in the NAND flash memory.

15. The nonvolatile semiconductor memory device according to claim 12, wherein the charge storage layer is a charge trap film including a silicon nitride film.

16. A method of manufacturing a nonvolatile semiconductor memory device comprising:
forming fin-shaped control gate electrodes on an insulating layer;
forming grooves in the control gate electrodes;
sequentially forming a first insulating layer, a charge storage layer, and a second insulating layer in the grooves;
forming, on the insulating layer, a polysilicon layer embedded in the grooves;
changing the polysilicon layer to a continuous grain silicon layer by crystal-growing the polysilicon layer in a direction of the grooves; and
removing, by thinning the continuous grain silicon layer, the continuous grain silicon layer extruded onto the grooves and forming a body layer having a channel region embedded in the control gate electrodes sequentially via the first insulating layer, the charge storage layer, and the second insulating layer.

17. The method of manufacturing a nonvolatile semiconductor memory device according to claim 13, wherein
the changing the polysilicon layer to the continuous grain silicon layer includes:
forming an insulating layer on the polysilicon layer;
forming, in the insulating layer, an opening for exposing a part of the polysilicon layer;
forming, on the insulating layer, a crystalline nucleus layer set in contact with the polysilicon layer via the opening; and
performing thermal treatment of the polysilicon layer with which the crystalline nucleus layer is set in contact.

18. The method of manufacturing a nonvolatile semiconductor memory device according to claim 17, wherein the crystalline nucleus layer is formed of Ni.

19. A method of manufacturing a nonvolatile semiconductor memory device comprising:
forming fin-shaped control gate electrodes on an insulating layer;
forming a sacrificial layer between the control gate electrodes;
forming grooves in the control gate electrodes and the sacrificial layer;
sequentially forming a first insulating layer, a charge storage layer, and a second insulating layer in the grooves;
forming, on the insulating layer, a polysilicon layer embedded in the grooves;
removing, by thinning the polysilicon layer, the polysilicon layer extruded onto the grooves and forming a body layer having a channel region embedded in the control gate electrodes sequentially via the first insulating layer, the charge storage layer, and the second insulating layer;
forming a hollow section formed under the polysilicon layer between the control gate electrodes by removing the sacrificial layer between the control gate electrodes; and
changing the polysilicon layer to a continuous grain silicon layer by performing thermal treatment of the polysilicon layer after forming the hollow section.

20. A method of manufacturing a nonvolatile semiconductor memory device comprising:
forming control gate electrodes on an insulating layer;
sequentially forming a first insulating layer, a charge storage layer, a second insulating layer, and a polysilicon layer on the control gate electrodes;
changing the polysilicon layer to a continuous grain silicon layer by crystal-growing the polysilicon layer in a direction crossing the control gate electrodes; and
forming, by processing the polysilicon layer to cross the control gate electrodes, a body layer arranged on the control gate electrodes to cross the control gate electrodes sequentially via the first insulating layer, the charge storage layer, and the second insulating layer.
